(19) United States
(12) Patent Application Publication
(10) Pub. No.: US 2026/0351455 A1
(43) Pub. Date: Nov. 5, 2026

(54) Resonantly Excited Magnonic-Crystal-Based Ultra-Sub-Wavelength Antenna for High Gain and Radiation Efficiency

(71) Applicant: Virginia Commonwealth University, Richmond, VA (US)

(72) Inventor: Supriyo Bandyopadhyay, Glen Allen, VA (US)

(21) Appl. No.: 19/742,772

(22) Filed: Jul. 15, 2026

Related U.S. Application Data
(63) Continuation-in-part of application No. 19/005,063, filed on Dec. 30, 2024.
Application No. 19/005,063 is a division of application No. 17/440,974, filed on Mar. 20, 2020, now Pat. No. 12,217,890.
(60) Provisional application No. 62/821,633, filed on Mar. 21, 2019.
(60) Provisional application No. 62/830,604, filed on Apr. 8, 2019.
(60) Provisional application No. 63/845,303, filed on Jul. 16, 2025.

(51) Int. Cl. H01F 10/32; B82Y 25/00; H01P 3/08; H03H 9/25; H04L 27/12; H04M 1/03; H10N 50/20

(52) U.S. Cl. CPC H01F 10/324; H01P 3/081; H03H 9/25; H04L 27/12; H04M 1/03; H10N 50/20; B82Y 25/00

(57) ABSTRACT

An extreme sub-wavelength antenna is actuated by causing magnetization oscillations in nanomagnets with alternating spin-orbit torque from a heavy metal nanostrip placed in contact with the nanomagnets and supplied with an alternating current. The magnetization oscillations produce spin waves which radiate electromagnetic waves in space to implement an electromagnetic antenna. Additionally, if the nanomagnets are magnetostrictive and the substrate is piezoelectric, then the system acts as a dual electromagnetic/acoustic antenna. Periodic expansion and contraction of the magnetostrictive nanomagnets caused by the magnetization oscillation launches an acoustic wave in a piezoelectric substrate placed underneath the nanomagnets thereby implementing an acoustic antenna. This novel actuation mechanism allows for an extreme subwavelength dual electromagnetic/acoustic antenna with an acoustic radiation efficiency over 50 times larger than the limit for an acoustic antenna of the same size actuated by an acoustic wave and operated at acoustic resonance and an electromagnetic radiation efficiency over 100 times larger than that of a conventional antenna activated by electromagnetic resonance. Antennas such as these have applications in many areas such as miniaturized speakers, micro electromechanical (MEMS) devices, acoustic mapping and analysis of biological specimens in a biochip or biosensor, medically implanted devices for health monitoring, stealth drones, etc.

Another extreme sub-wavelength electromagnetic antenna is actuated by launching a surface acoustic wave (SAW) in a piezoelectric substrate on which a periodic two-dimensional array of magnetostrictive nanomagnets is deposited to form an artificial multiferroic magnonic crystal (AMMC). The SAW subjects the nanomagnets to periodic mechanical strain which causes their magnetizations to precess owing to the inverse magnetostriction (or Villari) effect. These precessions generate spin waves in the nanomagnets which radiate electromagnetic waves in the surrounding medium to implement an antenna. At some specific frequencies determined by the size, shape, spacing and material of the nanomagnets, very efficient energy transfer takes place from the SAW to the spin waves causing the radiation efficiency of the antenna at these frequencies to become very high (>25%). Such a high radiation efficiency exceeds that of a conventional electromagnetic antenna of the same extreme sub-wavelength size by more than 100,000 times.

### CROSS REFERENCE TO RELATED APPLICATIONS

This application is a continuation-in-part (CIP) of U.S. Ser. No. 19/005,063, filed on Dec. 30, 2024, which was a divisional of U.S. Ser. No. 17/440,974 filed on Sep. 20, 2021, now U.S. Pat. No. 12,217,890, which was a national stage filing under Rule 371 from PCT/US2020/023941 filed Mar. 20, 2020, which claims benefit of U.S. provisional applications 62/821,633 filed on Mar. 21, 2019 and 62/830,604 filed on Apr. 8, 2019. This application also claim priority from U.S. provisional application 63/845,303 filed on Jul. 16, 2025.

### GOVERNMENT LICENSE RIGHTS

This invention was made with government support under grant number 2235789 awarded by the National Science Foundation (NSF). The government has certain rights in the invention.

### FIELD OF THE INVENTION

Embodiments generally relate to subwavelength antennas and, more particularly, extreme subwavelength antennas with high radiation efficiency.

### BACKGROUND

There is a strong interest in subwavelength antennas of all types (e.g., electromagnetic and acoustic) whose physical dimensions are much smaller than the wavelength of the radiation they emit. They can be miniaturized and integrated into a wide variety of modern communication systems, including but not limited to cell phones, embedded systems (e.g., wearable electronics), radio frequency identification (RFID) systems, medically implanted devices, and miniaturized communicators. However, such antennas typically have very poor radiation efficiency when they are excited at the radiation resonance (e.g. an electromagnetic antenna excited by an electromagnetic wave at electromagnetic resonance, or an acoustic antenna excited by an acoustic wave at acoustic resonance, etc.), because the radiation efficiency is typically bounded by (l/1)²[<1], where l is the antenna dimension and A is the wavelength of the emitted radiation. This limit is sometimes expressed as A/λ²[A<λ²], where A is the antenna emitting area and A is the wavelength of the emitted radiation.

Acoustic antennas with enhanced radiation efficiencies is an area of active research.
Landi et al. (M. Landi, J. Zhao, W. E. Prather, Y. Wu, L. Zhang, Phys. Rev. Lett. 2018, 120, 114301) studied an acoustic antenna predicated on the acoustic Purcell effect; it requires a cavity that modifies the acoustic density of states.
Zhang et al. (J. Zhang, Y. Chen, X. Liu, Sci. Rep. 2018, 8, 10049) studied a subwavelength acoustic antenna that uses Mie resonance and observed a 2.33-fold increase in the radiation intensity.
Zhang et al. (Z. Zhang, Y. Tian, Y. Wang, S. Gao, Y. Cheng, X. Liu, J. Christensen, Adv. Mater. 2018, 30, 1803229.) reported a 10-fold increase in the directivity of an acoustic antenna.

### SUMMARY

This disclosure presents novel antennas and antenna systems which overcome the traditional radiation efficiency limit by a much larger factor than previously reported. Embodiments herein achieve this objective using various configurations of nanomagnet arrays.

One embodiment and its derivatives achieve the objective of an extreme subwavelength dual acoustic and electromagnetic antenna by using spin-orbit torque in an array of nanomagnets generated by passing electrical current through heavy metal nanostrips in contact with the nanomagnets. Another embodiment and its derivatives achieve the objective by exciting an electromagnetic antenna at acoustic resonance instead of electromagnetic resonance by using magnetostrictive nanomagnets deposited on a piezoelectric substrate in which a surface acoustic wave is launched with electrodes to cause magnetization precession that radiates electromagnetic waves. Still another embodiment and its derivatives achieve the objective a nanomagnet array deposited on a topological insulator in which an alternating charge current is passed to inject spin current of alternating spin polarization into the nanomagnets to excite spin waves at the frequency of the charge current and these spin waves radiate electromagnetic waves of the same frequency in the surrounding medium to implement an antenna.

A first embodiment involves a novel on-chip extreme subwavelength magneto-elastic antenna whose radiation efficiency/intensity is at least 100 times larger than the theoretical limit for a resonantly driven antenna. The antenna comprises or is composed of nanomagnets deposited on a substrate. The nanomagnets are partially in contact with a heavy metal (e.g., Pt) nanostrip. The antenna is driven (by a current source) using an alternating charge current passed through the heavy metal strip that is in contact with the array of nanomagnets. Passage of alternating current through the nanostrip exerts alternating spin-orbit torque on the nanomagnets because of the giant spin Hall effect in the heavy metal and periodically rotates (or flips) their magnetizations. This disclosure may use the term “change” to refer to rotation and flipping collectively. The periodic rotation excites spin waves in the nanomagnets which radiate electromagnetic waves in the surrounding medium to implement an antenna. Additionally, if the nanomagnets are magnetostrictive, then during the rotation, they expand and contract, thereby setting up alternating tensile and compressive strain in the piezoelectric substrate underneath (that they are in elastic contact with). This leads to the generation of a surface acoustic wave in the substrate and makes the nanomagnet assembly act as an acoustic antenna as well. The frequency of the alternating charge current must be low enough that the period exceeds the time required to rotate the magnetization of the nanomagnets through a significant angle. So long as this requirement is met, the magnetizations of the nanomagnets rotate periodically with sufficient amplitude (or flip periodically) and emit an electromagnetic wave in addition to the acoustic wave. In an alternative embodiment, a topological insulator film delivers the spin-orbit torque to an array of nanomagnets instead of a heavy metal strip.

The examples show measured radiation efficiency ≈1% of such an acoustic antenna at the detected frequency, while the wavelength to antenna dimension ratio was ≈67:1. A normal acoustic antenna excited at acoustic resonance would have had a maximum radiation efficiency of ≈(1/67)²=0.02%. The acoustic antenna exemplified herein beat that limit by ≈50 times via actuating the antenna not at acoustic resonance, but by using a completely different mechanism involving spin-orbit torque originating from the giant spin Hall effect in Pt.

In yet another embodiment, an electromagnetic antenna is actuated by causing magnetization oscillations in magnetostrictive nanomagnets deposited on a piezoelectric substrate by launching a surface acoustic wave in the substrate. Different SAW frequencies are usable to cause the array to radiate at any frequency up to a predetermined limit, e.g., up to 1 GHz. This novel actuation mechanism allows for an extreme subwavelength electromagnetic antenna with a radiation efficiency over 10⁵ times larger than the limit for a conventional electromagnetic antenna actuated by an electromagnetic wave and operated at electromagnetic resonance. The array of nanomagnets define an emitting area (A) and, when driven, radiate an electromagnetic wave of a wavelength (λ), wherein the ratio A/λ² is on the order of 10⁻⁹. The radiation efficiency of such an extreme subwavelength antenna would have been limited to ~10⁻⁹ which is the “Harrington limit” had it been a conventional design, whereas the novel actuation mechanism resulted in a measured radiation efficiency >0.08% or 8×10⁻⁴ that exceeds the Harrington limit by more than five orders of magnitude.

Antennas such those disclosed by or based on the present disclosure have applications in many areas such as miniaturized speakers, micro electromechanical (MEMS) devices, acoustic mapping and analysis of biological specimens in a biochip or biosensor, medically implanted antennas for pacemakers and brain implants, ultrasmall stealth drones for defense and crimefighting, etc.

### BRIEF DESCRIPTION OF THE DRAWINGS

FIG. 1 is an extreme subwavelength antenna system comprising an array of nanomagnets.

FIG. 2A is a nanomagnet array comprising rows of nanomagnets.

FIG. 2B is the nanomagnet array of FIG. 2A at a different zoom.

FIG. 3 is an antenna system configured as an acoustic antenna.

FIGS. 4A and 4B illustrate the principle of actuating an antenna by spin-orbit torque from a heavy metal nanostrip.

FIG. 4C shows an exemplary nanomagnet shape involving a main body and a ledge.

FIGS. 5A and 5B show an extreme subwavelength antenna implemented with antiferromagnetic island on a piezoelectric substrate.

FIG. 5C shows an acoustic-to-electromagnetic converter where stress is generated with a surface acoustic wave (SAW).

FIG. 6 is an extreme subwavelength electromagnetic antenna comprising a topological insulator film.

FIG. 7A is a pattern for an acoustic antenna. The figure is not to scale.

FIG. 7B is a scanning electron micrograph of fabricated Co nanomagnets with Gaussian shaped ledges.

FIG. 8A is a scanning electron micrograph of the platinum lines overlying the nanomagnets.

FIG. 8B is a zoomed view of the micrograph from FIG. 8A showing the nanomagnets underneath the platinum line.

FIG. 9A is oscilloscope traces of the alternating voltage applied across the Pt lines to actuate the acoustic antenna (trace 902) and the alternating voltage detected at the interdigitated transducer (trace 901). They are respectively the input and output signals. The input voltage frequency is 3.63 MHz which is the resonant frequency of the interdigitated transducers (IDT) determined by the spacing of the IDT fingers and the velocity of surface acoustic wave in the substrate. Input voltage peak to peak amplitude is 22.5 V and the detected voltage peak-to-peak amplitude is 0.9 V.

FIG. 9B is oscilloscope traces of the alternating voltage applied across the Pt lines to actuate the acoustic antenna (trace 903) and the alternating voltage detected at the interdigitated transducer (trace 904). They are respectively the input and output signals. The input voltage frequency is 6.87 MHz and the peak-to-peak amplitude is 25.7 V, while the detected voltage peak-to-peak amplitude is 1.65 V.

FIG. 10A is a scanning electron micrograph of nanomagnet arrays in Sample A.

FIG. 10B is a scanning electron micrograph of nanomagnet arrays in Sample B.

FIG. 10C is a magnified image of one array in Sample B. The magnification is not enough to resolves individual nanomagnets.

FIG. 11A is a scanning electron micrograph of an array in Sample B.

FIG. 11B is a scanning electron micrograph of the same array as in FIG. 11A but at a higher magnification showing the nanomagnets are slightly elliptical with major axis dimension of ~360 nm, minor axis dimension of 330 nm, vertical edge-to-edge separation of ~65 nm and horizontal edge-to-edge separation of ~42 nm.

FIG. 12 shows Kerr rotation versus magnetic field of the array in Sample B. The Kerr rotation angle is proportional to the magnetic moment. There is ~100 Oe difference between the coercivities when the magnetic field orientation is rotated by 90°.

FIG. 13 is the power spectra of emissions detected by a dipole antenna coupled to a spectrum analyzer when the SAW frequency is 900 MHz. The antenna is placed >2 m from the sample. The spectra are shown for Sample A and the control sample. There is only ~1 dB difference between the two samples showing that the nanomagnets are not radiating sufficiently at this frequency. The input power to launch the SAW was 5 dbm (3.16 mW).

FIG. 14 is the power spectra of emissions detected when the SAW frequency is 144 MHz. Control 1 is the control sample corresponding to Sample A, and Control 2 is the one corresponding to Sample B. The input power was 5 dbm (3.16 mW). The detected emission from Sample B is 8 dB above that of Control 2 and is −73 dbm (50 pW).

FIG. 15A is a schematic of the TR-MOKE microscope showing the pump and probe beams and the geometry of the measurement. The probe beam spot covers about 4 nanomagnets.

FIG. 15B is the oscillations in time-resolved Kerr rotation in the absence of any externally launched SAW (top panel) and in the presence of an externally launched SAW at 144 MHz frequency with a power of −15 dBm (31.6 μW). The ultrashort laser pulses however independently induce high frequency SAW waves in the substrate, which cause high frequency oscillation of the magnetizations, leading to some Kerr oscillations. The oscillations are much more pronounced and have much larger amplitudes (before damping sets in) in the presence of the SAW.

FIG. 15C is the oscillations in time-resolved Kerr rotations at various SAW power levels. The SAW frequency is 144 MHz, which is the frequency used in the antenna experiment.

FIG. 15D is power spectral densities of the Kerr oscillations at launched SAW frequency of 144 MHz for various SAW power.

FIG. 16A is the oscillations in time-resolved Kerr rotations at various SAW power when the SAW frequency is 350 MHz.

FIG. 16B is power spectral densities of the Kerr oscillations at various SAW powers when the SAW frequency is 350 MHz.

FIG. 17 is reflection coefficient S11 as a function of input signal frequency.

FIG. 18 is a scanning electron micrograph of an example artificial multiferroic magnonic crystal (AMMC) according to one or more embodiments, showing an example AMMC nanomagnet array according to one or more embodiments, with a higher magnification image inset showing dimensional parameters relevant to the embodiments' resonant frequencies.

FIG. 19 is an example layout for an AMMC antenna for a spin-wave nano-antenna enabled by tripartite phonon-magnon-photon coupling, and showing contact pads for launch, in accordance with various embodiments, surface acoustic waves in different directions.

FIG. 20 shows a 3D perspective view of one example implementation of another AMMC according to one or more embodiments, with particular structural dimension and interspacing parameters relating to resonant frequencies.

FIG. 21 shows an example layout for another AMMC antenna for a spin-wave nano-antenna enabled by tripartite phonon-magnon-photon coupling, and showing contact pads for launching SAWs in the orientation 1 and orientation 2 directions

FIG. 22 shows measured frequency vs gain data illustrating that when the SAW frequency is not resonant with an intrinsic frequency, it generates an extrinsic mode at its own frequency, e.g., 1 GHZ, and shows that when SAW frequency is resonant with an intrinsic frequency, it amplifies the mode at that frequence while attenuating other intrinsic modes (see M3). Power is transferred from the SAW mode, showing phonon-magnon-coupling. Examples are 3.1 GHz and 4.2 GHz. These are intrinsic modes at the frequencies and when SAWs of these frequencies are launched the intrinsic powers at these frequencies are amplified by 7.2.

FIG. 23 shows power and phase data for Fsaw of 1 GHZ, 6 GHZ, 7 GHZ, and 8 GHz measured for an experimental implementation structured comparably to the FIG. 21 example.

FIG. 24 shows measurements of radiation patterns from an experimental implementation according to FIG. 23, in the nanomagnets plane, with beam steering, and the nanomagnet array energized with SAWs launched along the orientation 1 and the orientation 2.

### DETAILED DESCRIPTION

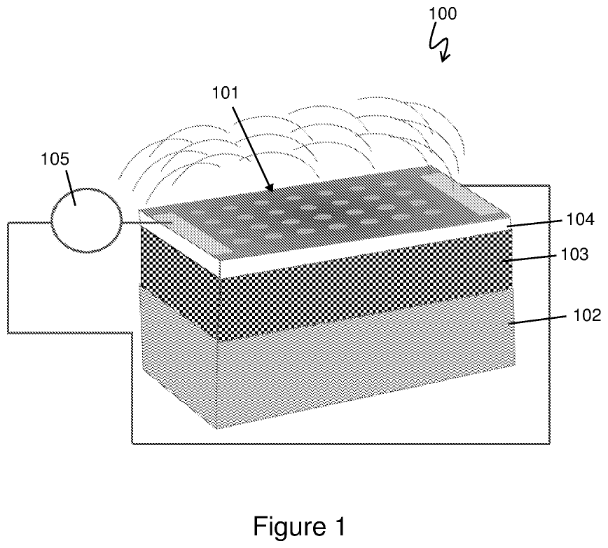

FIG. 1 shows an antenna system 100. The system 100 comprises an array 101 of nanomagnets over a substrate 102. One or more additional films or materials 103, 104, etc. may lie between the substrate 102 and the array 101. Alternatively, the array 101 (and the nanomagnets thereof) may be in direct contact with the substrate 102. In this disclosure, “nanomagnets” means a ferromagnetic material of a few tens to a few hundreds of nanometer dimensions (e.g., between 20 and 500 nm in the largest dimension). The nanomagnets are two-phase multiferroic, i.e. they are magnetostrictive and are in elastic contact with a piezoelectric material. Alternatively, they could be magnetostrictive and in electrical contact with a heavy metal. One or more additional films may be interposed between the nanomagnet and heavy metal. “Heavy metals” means metals and other materials that can sustain a current flow and exhibit strong spin-orbit coupling. Passage of current through a heavy metal exerts a spin-orbit torque on the nanomagnet that they are in contact with. The magnetizations of the multiferroic nanomagnets (that is to say, the orientations or directions of their polarizations) may be changed by an electric field applied on the piezoelectric component of the multiferroic nanomagnet that exerts a strain on the nanomagnets. The magnetizations of nanomagnets in electrical contact with a heavy metal can be changed by passing electric current through the heavy metal that results in the exertion of a spin-orbit torque on the nanomagnets. If the electric field or the current oscillates in time, then so will the magnetizations. These oscillations radiate electromagnetic waves, thereby implementing an electromagnetic antenna that transmits electromagnetic waves.

Because the radiation is caused by oscillating magnetizations and not oscillating charges, the antenna's radiation efficiency can beat the (l/□)² limit. At the same time, these magnetization oscillations make the nanomagnets expand and contract periodically, which causes a periodic strain on the substrate underneath. This generates a surface acoustic wave in the substrate, making the system also act as an acoustic antenna that transmits acoustic waves.

The system can also act as a receiving antenna. If an electromagnetic wave is incident on the nanomagnets, it will make their magnetizations oscillate, which will generate periodic spin pumping into the heavy metal and hence an alternating voltage across it because of the inverse spin Hall effect. In this case, the array of nanomagnets acts as a receiving antenna. Similarly, if an acoustic wave is incident on the nanomagnets, the nanomagnets will respond to the wave by periodically expanding and contracting, which will make their magnetizations oscillate due to the inverse magnetostriction effect and the resulting spin pumping into the heavy metal will cause an oscillating voltage owing to the inverse spin Hall effect. Thus, the array can also act as a receiving acoustic antenna.

The array 101 of nanomagnets functions as the antenna element of system 100. Depending on the specific configuration, the array 101 may transmit a signal, receive a signal, or both transmit and receive. The term “array” as used herein may refer to a single array or multiple arrays. Thus “an array” may comprise a plurality of arrays. Generally the smallest transmitting or receiving element of an array is a nanomagnet.

Antenna system 100 further comprises a module 105. Module 105 may be a transmitter, a receiver, or a transceiver. Module 105 may be configured to deliver power to or near the array 101. Module 105 may be configured to control the intensity, waveform, frequency, or amplitude of signals sent to the array 101 and emitted from the array 101. Module 105 is configured or configurable to periodically change magnetizations of the nanomagnets such that the array 101 emits one or more waves (one or more forms of radiation). In addition or in the alternative, module 105 is configured or configurable to filter, convert, and/or process a signal detected by array 101.

The antenna system 100 may be configured to transmit (emit) electromagnetic and/or acoustic waves. The antenna system 100 may be configured to receive electromagnetic and/or acoustic waves, converting such incoming signal to an electrical signal such as a current or voltage that varies based on a predetermined signal or message content.

The individual nanomagnets as illustrated in FIG. 1 are elliptical in shape. Different embodiments may have differently shaped nanomagnets. That is, an array 101 may have nanomagnets which are circular, elliptical, square, rectangular, polygonal, or any of variety of other shapes. The shape may affect the direction of the poles and may be selected to control the propensity of the nanomagnet to flip or rotate under predetermined environmental conditions, e.g., the strength of an applied electric or magnetic field.

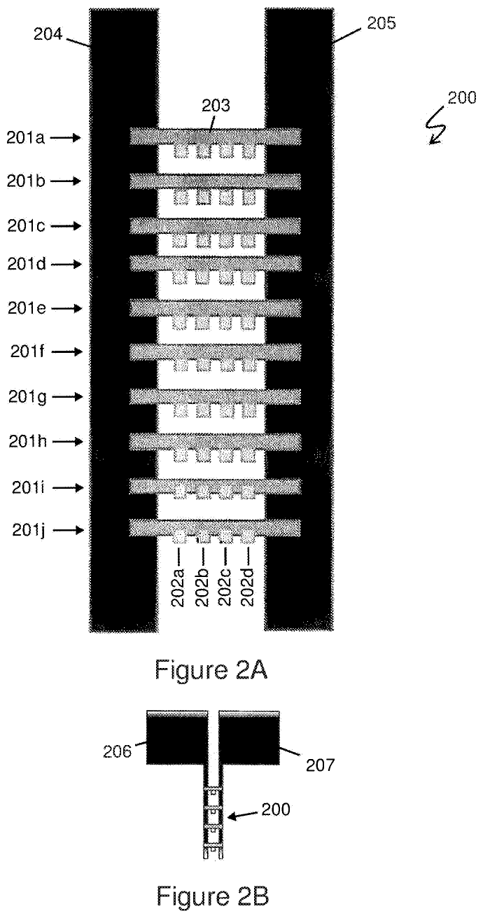

FIG. 2A shows another array 200 of nanomagnets. The array comprises a plurality of rows (which may be called columns depending on the reference frame). As illustrated FIG. 2A shows ten rows 201a through 201j, but embodiments may have significantly more than ten rows, e.g., hundreds or thousands of rows. Each row comprises a plurality of nanomagnets. As illustrated FIG. 2A shows four nanomagnets per row, e.g., row 201j has nanomagnets 202a, 202b, 202c, and 202d. To avoid overcrowding FIG. 2A, only the nanomagnets of row 201j are labeled. Embodiments may however have tens, hundreds, thousands, or more nanomagnets per row (or column). The nanomagnets of any one row are collectively in contact with a heavy metal strip 203. To avoid overcrowding FIG. 2A, only the heavy metal strip 203 of row 201a is labeled, but each row has a separate heavy metal strip. All of the heavy metal strips 203 are electrically connected with conductive contacts 204 and 205. The radiation from the antenna may be increased or decreased by respectively increasing or decreasing the number of nanomagnets in the array.

FIG. 2B shows a zoomed out portrayal of the array 200. At this zoom only four rows are distinguishable. FIG. 2B shows that conductive contacts 204 and 205 are respectively conductively connected with electrodes 206 and 207. The connection to successively larger conductive elements may be used to provide for the connection of the antenna array with other circuitry elements. As a reminder of scale of the illustrated elements, each nanomagnet may be, for example, only 100-500 nm in length and/or 100-500 nm in width.

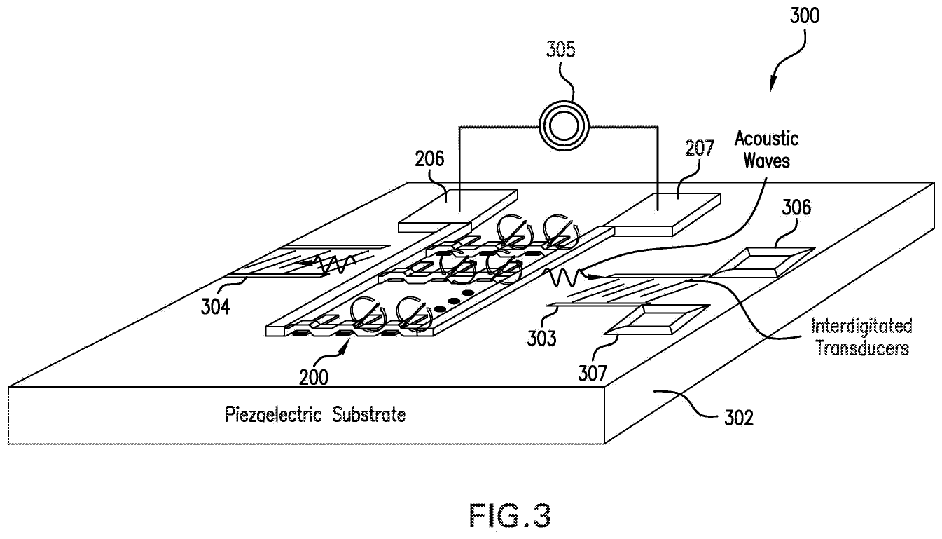

FIG. 3 is a schematic that incorporates the exemplary array 200 into a larger system 300 that includes both transmitting and receiving elements for respectively emitting and detecting transmission signals which are surface acoustic waves (SAWs). The substrate 302 is a piezoelectric substrate and the nanomagnets are magnetostrictive. The nanomagnets and substrate 302 are arranged with respect to one another such that physical forces in one transfer or are transferable to the other. Generally this is most readily achieved by the nanomagnets and substrate 302 being in direct physical contact with one another. However, some embodiments may have one or more materials (e.g., layers, films) partially or completely between the piezoelectric substrate and the nanomagnets.

In FIG. 3 the array 200 is only illustrated with three rows for simplicity of illustration. As discussed above, the actual number of rows may be tens, hundreds, or thousands. The number of rows may be configured according to the signal strength desired or required of the antenna as determined prior to manufacture. Generally, more nanomagnets, and thus more rows, corresponds with greater emitted signal strength (or sensitivity to received signals). The electrodes 206 and 207 are connected to a driver 305 which may comprise or else is connected to an AC source. The electrodes 206 and 207 are conductive traces and may be, for example, gold or aluminum. The driver 305 is configured to periodically change magnetizations of the nanomagnets of the array 200 such that the array emits one or more waves, in this case acoustic waves.

The receiving elements in system 300 are interdigitated transducers 303 and 304. Two receiving elements 303 and 304 are shown, but systems like system 300 may have only one or, alternatively, a plurality (e.g., 3, 4, 5, tens, or more). A transducer 303 is connected to electrodes 306 and 307 which facilitate electrical connection with downstream circuitry. FIG. 3 shows the antenna-transmitter system (comprising the nanomagnet array and driver) and the antenna-receiver system (comprising the interdigitated transducers) physically situated near one another. This proximity may be representative for some embodiments but particularly functions in FIG. 3 the illustrative objective of fitting both systems in the same drawing. In practice, the distance over which the signal is transmitted may vary substantially, depending on the particular use scenario. The distances over which a surface acoustic wave (SAW) can travel depends on the attenuation constant which, in turn, depends on the material in which the SAW propagates and also the crystallographic orientation along the direction of propagation. Typically, the attenuation constant in suitable materials is very small. Hence the SAW can easily propagate over several tens of cm (e.g., at least 50, 60, 70, 80, or 90 cm) without losing much signal strength. The direction of the SAW propagated by the nanomagnet array 200 is generally in all directions on the surface plane of the piezoelectric substrate 302. That is to say the exemplary antenna is omnidirectional in the plane of the piezoelectric substrate.

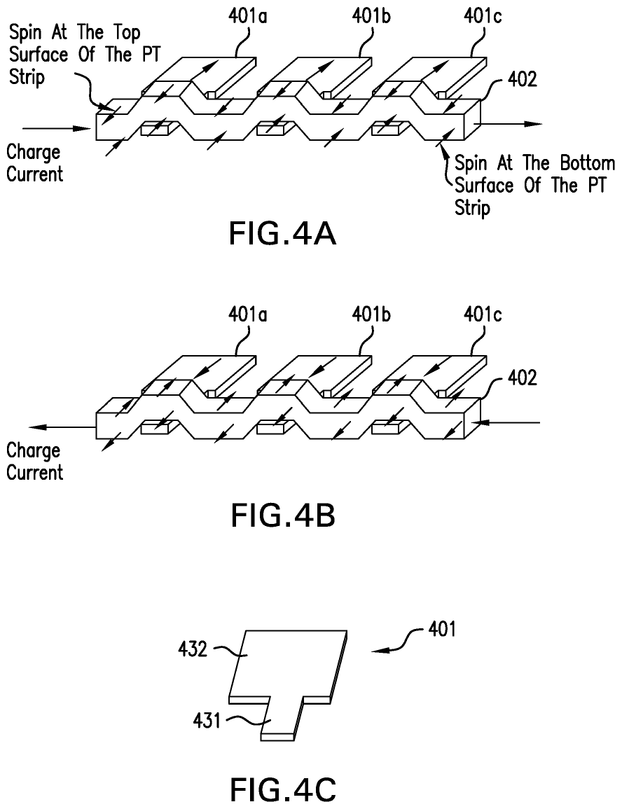

FIGS. 4A and 4B illustrate the mechanism by which the magnetizations of the nanomagnets are periodically changed, resulting in the emission of one or more waves. Each of FIGS. 4A and 4B show the same three nanomagnets 401a, 401b, 401c belonging to the same row of an array such as array 200 (see FIGS. 2A, 2B, and 3).

FIG. 4C shows a perspective view of a single nanomagnet 401, representative of nanomagnets 401a, 401b, and 401c. Each nanomagnet 401 comprises a ledge 431 and a remaining portion 432. The remaining portion 432 may be square, for example, with the ledge 431 being substantially smaller in surface area and volume than the remaining portion 432. Portions 431 and 432 may be a single body produced in a single step or by the same manufacturing steps (e.g., of a photolithographic process).

Returning to FIGS. 4A and 4B, a single heavy metal strip 402 is arranged across the ledge of each of the nanomagnets 401a, 401b, and 401c. That is to say, each ledge is underneath the heavy metal nanostrip. An exemplary heavy metal is platinum. The bulk of each nanomagnet (the portion 432) is outside the strip 402 and hence its expansion/contraction is not clamped by the nanostrip. Only the ledge is clamped.

FIG. 4A shows the application of a charge current to the heavy metal nanostrip in a first direction of current, whereas FIG. 4B shows the application of a charge current to the heavy metal nanostrip in a second direction of current, where the first and second directions are opposite. Both directions may be result of an applied alternating current. Thus in practice, the driver would periodically alternate the current between these two states. When a charge current is injected into the nanostrip, the top and bottom surfaces of the nanostrip become spin-polarized because of the giant spin Hall effect in the heavy metal (here, Pt). The two surfaces have antiparallel polarizations. The polarizations of spins in either surface depends on the direction of the current and changes sign when the current reverses direction. The accumulated spins in the bottom surface of the nanostrip 402 diffuse into the ledges 431 that they are in contact with, and from there into the remaining portion of the nanomagnets 401a, 401b, and 401c. This transfer exerts a spin-orbit torque on the nanomagnets 401a, 401b, and 401c and rotates their magnetizations. FIGS. 4A and 4B are labeled with a number of arrows to show the spin on top surfaces of the nanostrip 402, the bottom surfaces of the nanostrip 402, and in the nanomagnets 401a, 401b, and 401c.

When the driver reverses the direction of the injected charge current, the change in current reverses the spin polarization of the bottom surface of the nanostrip and hence rotates the magnetizations of the nanomagnets in the opposite direction because the spin-orbit torque will reverse direction. Generally, this will happen only as long as the period of the current is longer than the time of magnetization rotation. Thus, if the driver passes an alternating current through the nanostrip, it will rotate or flip the magnetizations of the nanomagnets periodically, as long as the frequency of the current is considerably smaller than the inverse of the spin rotation times of the nanomagnets. One or more of the shape, size, and material of the nanomagnets, the nanostrip, and the physical arrangement of the nanomagnets and nanostrips may be configured at the time of manufacture to set the threshold to a predetermined value.

The alternating rotation of the nanomagnets in the array causes the array to emit an electromagnetic wave, hence the system 300 in FIG. 3 will act as an electromagnetic antenna. At the same time, the nanomagnets will periodically expand and contract because they are magnetostrictive, thus executing a “breathing mode” oscillation. This will generate periodic strain in the piezoelectric substrate 302 underneath the nanomagnets and set up a SAW that is detectable with interdigitated transducers (IDTs). Thus, the system 300 acts as a dual electromagnetic and acoustic antenna. The driver 305 may be configured to modulate a frequency of the emitted wave solely by controlling a frequency of the alternating charge current.

The wavelength of the acoustic wave may be determined solely by the frequency of the alternating charge current (which is the dominant frequency of the generated acoustic wave) and the velocity of acoustic wave propagation in the piezoelectric substrate. Therefore, it has no relation to the size of the nanomagnets (antenna elements). The antenna elements may be much smaller than the size of the acoustic wavelength. The result is a subwavelength acoustic antenna with a radiation efficiency that exceeds the theoretical limit for an acoustic antenna excited at acoustic resonance.

From the physics perspective, electrical signals (photons) are used to generate acoustic waves (phonons). The antenna converts photons in the input (low-frequency electromagnetic) alternating signal applied to the Pt strip to magnons via the spin Hall effect (or spin-orbit torque) and then to phonons in the surface acoustic wave via magnetoelastic coupling, which are finally detected at the IDT. The overall efficiency of this three-step process is at least ~1%.

Example 1 below show an extreme subwavelength acoustic antenna that emits acoustic waves (in addition to electromagnetic waves) with an efficiency of ~1%. The antenna dimension was 67 times smaller than the acoustic wavelength. The antenna is not driven at acoustic resonance, thereby avoiding the expected efficiency limit. For instance, for an antenna 67 times smaller than the acoustic wavelength, the efficiency of such antenna if driven at acoustic resonance would be limited to (1/67) 2=0.02%. The present embodiment overcomes that limit and achieves an efficiency of ~1%, which is 50 times larger than the limit. This is achieved using a principle of actuation different from acoustic resonance. The antenna dimension can be made substantially smaller than 1/67 times the wavelength with still reasonable radiation efficiency.

The excitation frequency (frequency of the electrical signal applied to the Pt nanostrip to produce the giant spin Hall effect) in Example 1 was around 3.6 MHz. The maximum allowable frequency (or alternately the minimum signal period) is determined by the time it takes for the nanomagnets' magnetizations to rotate over a significantly large angle. The signal period must exceed the latter time by a factor of e.g. ≈10 to ensure that nearly all the nanomagnets have ample time to rotate their magnetizations through a large enough angle and produce a strain in the piezoelectric substrate underneath. The time taken by the magnetization to rotate through a large enough angle depends on the size, shape, nanomagnet material, and also the strength of the spin-orbit torque, which, in turn, is determined by the spin-orbit interaction strength in the heavy metal (in this case platinum) and the magnitude of the current injected into it. For reasonable values of these parameters, the switching time is estimated to be no less than ~1 ns. (Past simulations by the inventors based on the Landau-Lifshitz-Gilbert equation suggests that the switching time is on the order of 1 ns.) Of course, there will be distribution of the switching time because of defects in the nanomagnets, pinning sites, variations in shape and size, etc. As a result, some embodiments may use a safe estimate threshold for switching of 10 ns, which would then limit the maximum frequency to 100 MHz. This is high enough for many on-chip acoustic applications.

The system 300 of FIG. 3 was described above according to a configuration in which antenna array 200 transmitted a signal and IDTs 303 and 304 received the signal. In some embodiments, the nanomagnet array 200 may instead by configured as the receiving element. The transmitting element in such an arrangement may be another nanomagnet array like array 200, or else it may be IDTs. To recap, an antenna according to the present disclosure may be configured as a transmitting antenna, receiving antenna, or both. Antennas according to the present disclosure may furthermore be configured as an electromagnetic antenna, acoustic antenna, or both.

In FIG. 3, the IDTs 303 and 304 may be used as input ports, and the two terminals or electrodes 206 and 207 of the heavy metal strips may be used as output ports. An oscillating electrical signal applied at the input port produces an oscillating electrical signal at the output port because of reciprocity. The input signal at the IDT 304 or 303 launches a SAW in the substrate 302. The SAW in the substrate 302 periodically rotates the magnetizations of the magnetostrictive nanomagnets owing to the Villari effect. This results in periodic spin pumping into the heavy metal (e.g., Pt) lines, resulting in an alternating spin current which would have been converted into a charge current by the inverse spin Hall effect, resulting in an oscillating electrical signal across the heavy metal lines. However, to observe the reciprocal effect, the design should be such that sufficient spin pumping can occur. Here, the details of system 300 may differ from what is disclosed above in FIGS. 4A, 4B, and 4C. When configuring system 300 for optimal performance as an acoustic antenna that transmits a SAW, the exemplary nanomagnets 401 included ledges to avoid clamping. Such configuration may preclude sufficient spin pumping because a small section of the nanomagnets are in contact with the Pt strip. Therefore, the reciprocal effect is small in the arrangement of heavy metal strip and nanomagnets represented by FIGS. 4A, 4B, and 4C. Accordingly, for embodiments in which an array 200 of a system 300 is configured for receiving an acoustic wave and converting it to an electrical signal, the nanomagnets should have a larger overlap with the adjacent heavy metal strip for more efficient spin pumping.

The actuation of the nanomagnets as described in the preceding paragraph is similar for a configuration in which the array 200 is used for emitting an electromagnetic wave as a result of actuation by an acoustic wave. The physics underlying configuration of the array 200 as electromagnetic antenna actuated by an acoustic wave is a converse of the physics underlying the configuration of the array 200 as an acoustic antenna actuated by an alternating current that causes alternating spin-orbit torque. Configured as an electromagnetic antenna actuated by an acoustic wave, array 200 of system 300 converts phonons to magnons to photons in order to realize a subwavelength electromagnetic antenna implemented with magnetostrictive nanomagnets that were periodically strained with a surface acoustic wave.

Exciting the antenna at acoustic resonance instead of electromagnetic resonance allows for considerable miniaturization of the antenna. Since the acoustic wave velocity in many piezoelectric solids is roughly five orders of magnitude smaller than the speed of light in vacuum, the acoustic wavelength is five orders of magnitude smaller than the electromagnetic wavelength at the same frequency. Consequently

$$A / {λ}_{ac}^{2} ∼ 1 {0}^{10} \times A / {λ}_{EM}^{2} ,$$

where A is the radiating area of the antenna, λ_{ac} is the acoustic wavelength and λ_{EM} is the electromagnetic wavelength.

The surface acoustic waves were also found to amplify the magnetization response of nanomagnets resonating in GHz frequencies, which may have different applications of its own. These extreme sub-wavelength antennas allow dramatic downscaling of communication systems and may open up new high frequency applications. They may also allow the miniaturization of two-dimensional phased array antennas for electronic beam steering with the entire array occupying an area much smaller than the square of the emission wavelength.

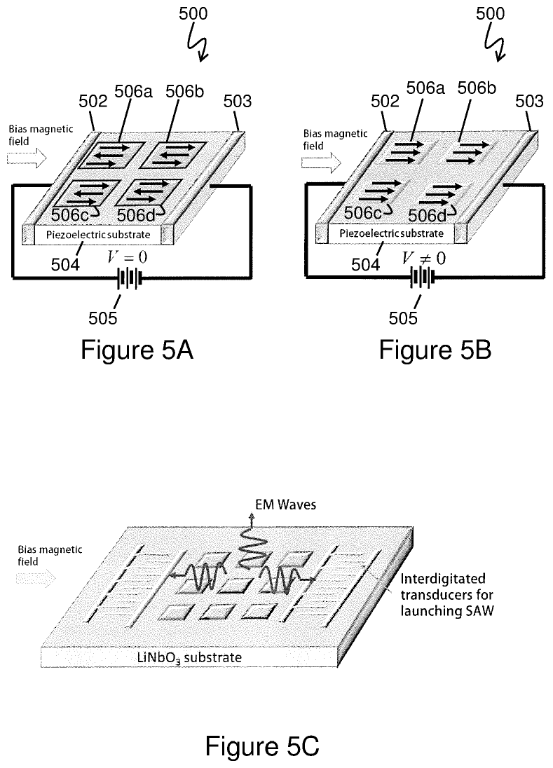

FIGS. 5A and 5B illustrate yet a further embodiment. Here a sub-wavelength electromagnetic antenna 500 is implemented with anti-ferromagnets that undergo a metamagnetic transition to a ferromagnetic state at a critical temperature. For example, FeRh is an antiferromagnet below 350 K temperature, but becomes a ferromagnet above that temperature. The transition temperature is suppressed to below room temperature using strain. Thus, by applying strain, antiferromagnetic FeRh is converted to ferromagnetic FeRh at room temperature.

In FIG. 5A, islands 506a, 506b, 506c, and 506d of anti-ferromagnetic material are on a piezoelectric substrate 504. Islands (of lateral dimensions such as 100 nm and thickness 5-10 nm) may be sputter deposited on a patterned piezoelectric substrate. The islands may be made of, for example, FeRh. The piezoelectric substrate may be LiNbO₃ for example. The antiferromagnetic state has no net magnetization.

In FIG. 5B a bias electric field is induced by an applied voltage from power source 505 applied between electrodes 502 and 503 on opposite sides of the substrate 504. Application of a voltage across the piezoelectric substrate strains the islands such that they undergo a metamagnetic transition to the ferromagnetic phase. The strain in the substrate 505 resulting from the bias field causes the islands 506a, 506b, 506c, and 506d to convert to a ferromagnetic state with orientations fixed in a common direction.

Application of an oscillating voltage to the piezoelectric periodically generates a magnetic field in the direction of the bias field, and this oscillating field will produce an electromagnetic wave. The islands 506a, 506b, 506c, and 506d thus become an extreme subwavelength electromagnetic antenna.

The highest frequency that is producible is limited by the piezoelectric response time of 10-100 picoseconds (ps) and hence is between 10 and 100 GHz (a higher frequency than embodiments described above since we are relying on the metamagnetic transition and not the Giant Spin Hall Effect, spin diffusion and magnetic reversal of the nanomagnets). The electromagnetic wavelength at these frequencies is in the range 0.3-3 mm, while the antenna dimension is ~100 nm, making the wavelength to antenna dimension ratio at least 3000:1.

FIG. 5C shows an acoustic-to-electromagnetic converter 500 where the stress is generated with a surface acoustic wave. To implement an antenna for lower frequencies (~1 GHZ), then the strain in the piezoelectric can also be produced by launching a surface acoustic wave of frequency ≈1 GHz in the substrate.

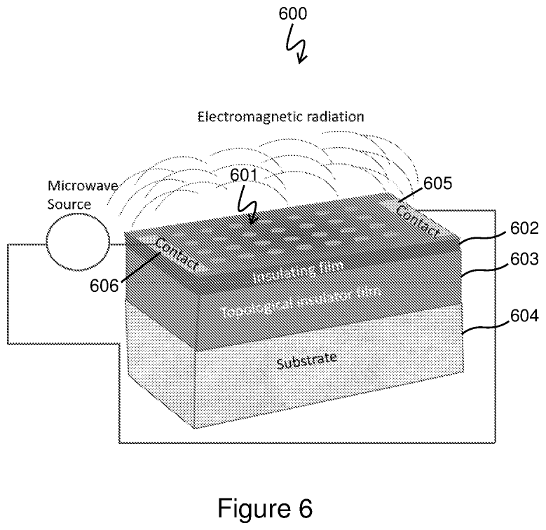

FIG. 6 shows as yet a further embodiment an extreme sub-wavelength electromagnetic antenna 600. The antenna comprises an array 601 of nanomagnets arranged on an insulating film 602 over a topological insulator film 603 deposited on a substrate 604. An alternating current is passed through the topological insulator film via contacts 605 and 606. The contacts may be placed directly on top of the topological insulator film. The topological insulator film alternately injects spins of opposite polarization into the nanomagnets. This makes their magnetizations oscillate and emit electromagnetic radiation. The spin Hall angle associated with spin injection from a topological insulator is larger than that associated with spin injection from a heavy metal. Hence, a topological insulator may deliver a stronger spin-orbit torque and increase the radiation efficiency as well as the output power. The driver in this embodiment may be a microwave source or any alternating current source that includes a microwave source.

### EXAMPLES

### Example 1. Demonstration of an Extreme Subwavelength Nanomagnetic Acoustic Antenna Actuated by Spin-Orbit Torque from a Heavy Metal Nanostrip

The nanomagnets and Pt strip were fabricated on a 128° Y-cut LiNbO₃ substrate. The substrate was spin-coated with bilayer polymethyl methacrylate (PMMA) e-beam resists of different molecular weights to obtain good undercut: PMMA 495 diluted 4 vol % in Anisole, followed by PMMA 950 also diluted 4 vol % in Anisole. The spin coating was carried out at a spin rate of 2500 rpm. The resists were subsequently baked at 110 °C for 5 min. Next, electron-beam lithography was performed using a Hitachi SU-70 scanning electron microscope (at an accelerating voltage of 30 kV and 60 picoamp (pA) beam current) with a Nabity NPGS lithography attachment. Finally, the resists were developed in methyl isobutyl ketone and isopropyl alcohol (1:3) for 270 s followed by a cold IPA rinse. For nanomagnet delineation, a 5 nm thick Ti adhesion layer was first deposited on the patterned substrate using e-beam evaporation at a base pressure of ≈2×10⁻⁷ Torr, followed by the deposition of Co. Pt was deposited similarly. The lift-off was carried out using Remover PG solution.

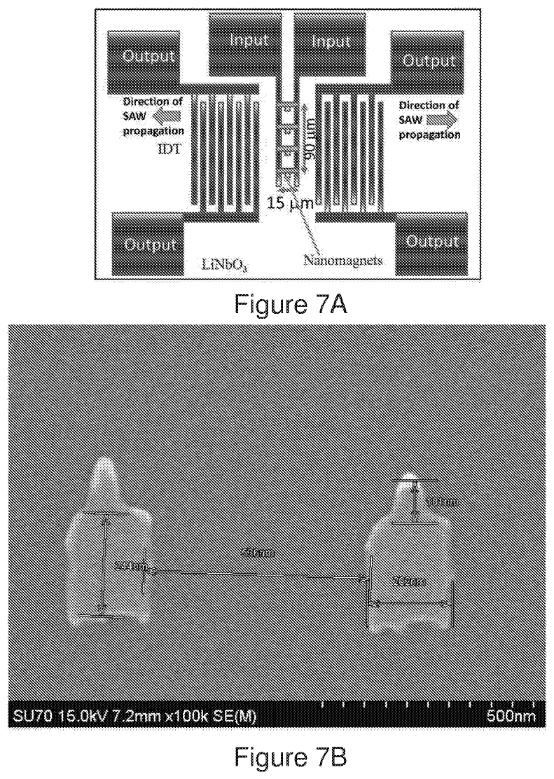

FIG. 7A shows the pattern of the acoustic antenna (with the nanomagnets, Pt lines, contact pads to the Pt lines, and IDTs). FIG. 7B shows a scanning electron micrograph of the fabricated nanomagnets. The nanomagnets are rectangular with long dimension ≈250 nm, short dimension ≈200 nm, and the ledge length is ≈100 nm. The ledge has a tapered shape and the full width at half maximum is ≈70 nm.

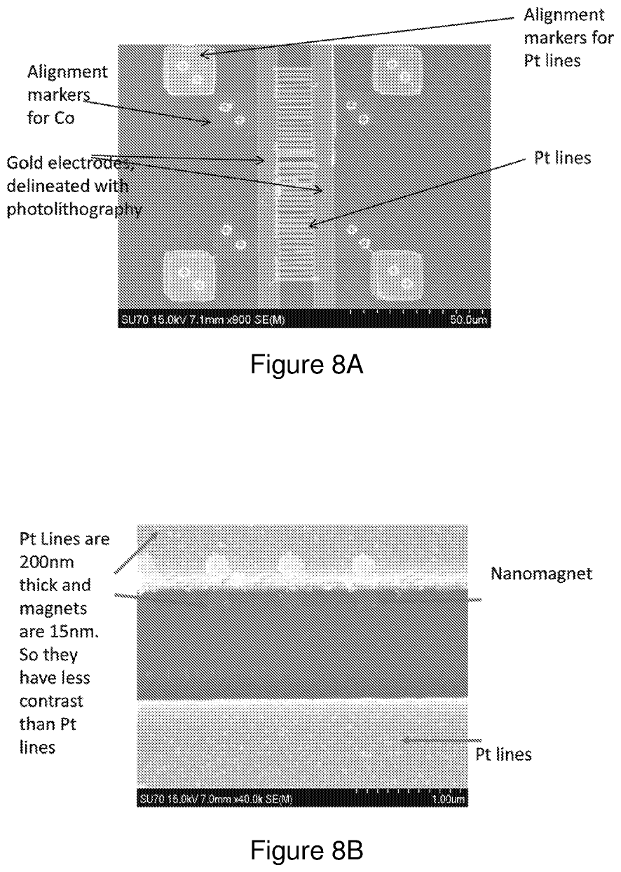

FIGS. 8A and 8B show scanning electron micrographs of the Pt line and nanomagnet assembly. There are 40 Pt lines and hence 40 rows of nanomagnets that are contacted.

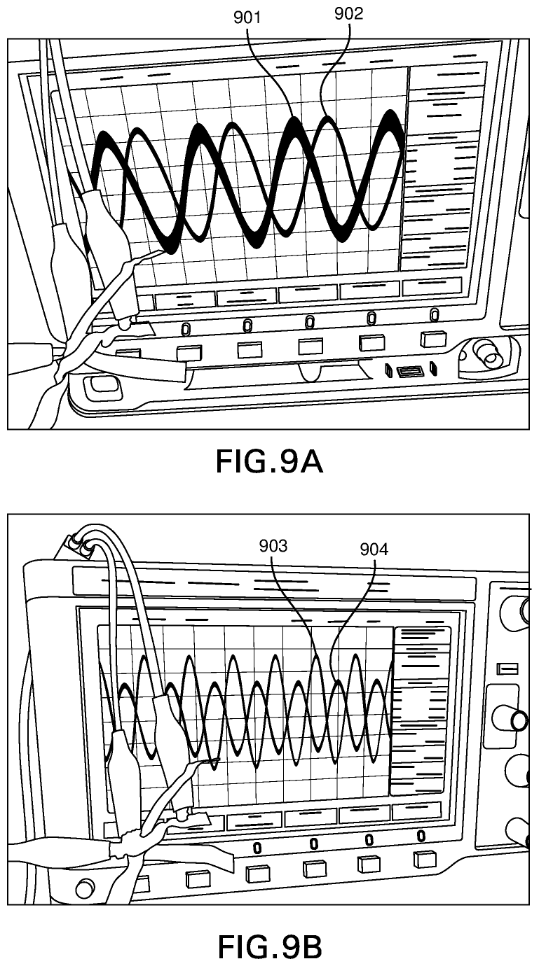

FIGS. 9A and 9B show both the oscilloscope traces of the sinusoidal voltage applied across the Pt lines to actuate the acoustic antenna via spin-orbit torque and the voltage detected at the IDT. These traces are shown for two frequencies, 3.63 MHz which is the resonant frequency of the IDT, and 6.87 MHz.

The resistance of the 40 parallel Pt lines varied between 98 and 108 ohms from sample to sample. Therefore, the resistance of each Pt nanostrip or line is on the order of 4 kilo ohms (kΩ). For the case in FIG. 9A, the input voltage of 11.25 V peak-to-zero (measured from the oscilloscope trace) will produce a current of 2.8 mA peak-to-zero in a Pt line. The line has a length of 15 μm, width 1 μm, and thickness 200 nm. Therefore, the peak current density in each Pt line is 1.4×10¹⁰ A m⁻², which should be well above the critical current density needed to produce sufficient spin-orbit torque. In the case of FIG. 9B, the input voltage of 12.85 V peak-to-zero produced a peak-to-zero current of 3.21 mA in a Pt line, resulting in a peak-to-zero current density of 1.6×10¹⁰ A^{m-2} in each line.

The input power to the acoustic antenna is calculated as

$${V}_{in}^{2} / 2 {R}_{Pt}$$

where Vᵢₙ is the peak-to-zero input voltage and Rₚₜ is the resistance of the 40 Pt lines in parallel. For the case in FIG. 9A, this quantity is 633 mW, while for the case in FIG. 9B, it is 825 mW.

In order to calculate the radiation efficiency, first the power in the acoustic wave that has been produced is determined. The power carried by an acoustic wave of amplitude φ is given by

$$P = \frac{1}{2} {γ}_{0} \frac{W}{λ} {φ}^{2} \qquad ( 1 )$$

where γ₀ is the characteristic admittance of the SAW line and has a value of 2.1×10⁻⁴ S for LiNbO₃, W is the width of the IDT and λ is the wavelength of the SAW. The IDTs were designed and fabricated for W/λ=40.

Neglecting capacitive and inductive effects, the voltage Vₒᵤₜ detected at the IDT is related to the SAW amplitude q as

φ≈μVₒᵤₜ (2)

where μ is the response function of an IDT operating in the transmitting mode. For the present system, this quantity was calculated as ≈2 (see V. Sampath, N. D'Souza, D. Bhattacharya, G. M. Atkinson, S. Bandyopadhyay, J. Atulasimha, Nano Lett. 2016, 16, 5681.) Hence, for the case shown in FIG. 9A (where Vₒᵤₜ=0.45 V peak-to-zero as seen in the oscilloscope trace) φ=0.9 V peak-to-zero and for the case shown in FIG. 9B, φ=1.6 V peak-to-zero. Therefore, from Equation (2), the SAW power produced in the two cases are 3.4 and 10.7 mW, respectively. The corresponding efficiencies of SAW production are 0.54% and 1.3%, respectively. These numbers are approximate because of some simplifying assumptions such as neglecting inductive and capacitive effects. It is also assumed that the IDT detection efficiency is 100%, which is an overestimate, especially at frequencies that are not the IDT resonant frequency. Hence, the estimates of the antenna efficiencies presented here are conservative.

In the LiNbO₃ substrate, the acoustic wave velocity is ~3300 m s⁻¹. Therefore, for a frequency of 3.63 MHz, the acoustic wavelength is ≈1 mm. The nanomagnet assembly acting as the antenna has a dimension of ≈15 μm in the direction of SAW propagation. Hence the ratio of acoustic wavelength to antenna dimension is ≈67, making it an extreme subwavelength antenna (an antenna whose linear dimension is smaller than one-tenth of the wavelength). If the antenna was excited by an acoustic wave and driven at the acoustic resonance, the radiation efficiency would have been limited to ≈(1/67)²=0.02%. The measured efficiency here is about 50 times larger. The present embodiment was able to overcome the limit because the antenna was actuated via spin-orbit torque as opposed to being driven with an acoustic wave. It was considered whether the output voltage detected at the IDT (shown in FIGS. 9A and 9B) could have been due to direct electromagnetic pick up through the air from the input, instead of being from an acoustic wave in the substrate. Electromagnetic pickup, however, could never have produced the phase shifts (time delay) seen between the input and output signals in FIGS. 9A/9B. The measured average distance between the input and output ports is ~6 mm and the time Δt that it would take an electromagnetic wave to traverse this distance is 20 ps. At a frequency f of 3.63 MHz (FIG. 9A), this would produce a phase lag of 2πfΔt=4.56×10⁻⁴ radians between the output and input, which is much smaller than what is observed.

For an acoustic wave traveling in the substrate, with a velocity 5 orders of magnitude smaller than that of an electromagnetic wave propagating through the air, Δt will be five orders of magnitude larger and the phase shift at this frequency will be 45.6 radians=(14π+1.62) radians. When the modulo 2π value of this phase shift is taken, this is 1.62 radians. The observed phase shift is about 2.2 radians which is much closer to the acoustic phase shift than the electromagnetic phase shift. This gives confidence that the detected signal is not due to electromagnetic pick up.

Repeating this exercise for the 6.87 MHz frequency will yield an electromagnetic phase shift of 8.63×10⁻⁴ radians and an acoustic phase shift of 86.3 radians=(26π+4.6) radians. The modulo 2π value of this phase shift is 4.6 radians which is close to the observed value of 3.3 radians. This again gives confidence that the observed output voltage at the IDT is indeed due to the generated surface acoustic wave.

In conclusion, this Example demonstrates an acoustic antenna actuated by the spin-orbit torque from a heavy metal nanostrip. The use of this novel actuation mechanism allows for an extreme subwavelength acoustic antenna with a radiation efficiency over 50 times larger than the limit for an acoustic antenna actuated by an acoustic wave and operated at acoustic resonance.

### Example 2. Extreme Sub-Wavelength Magneto-Elastic Electromagnetic Antenna Implemented with Multiferroic Nanomagnets

This Example demonstrates an extreme sub-wavelength EM antenna whose radiation efficiency exceeds the

$$A / {λ}_{EM}^{2}$$

limit by a factor exceeding 10⁵.

An extreme-sub-wavelength EM antenna was constructed as an array of magnetostrictive (Co) nanomagnets of dimension ~300 nm fabricated on a piezoelectric 128° Y-cut LiNbO₃ substrate. The substrate was spin-coated with bilayer polymethyl methacrylate (PMMA) e-beam resists of different molecular weights to obtain good undercut: PMMA 495 diluted 4% by volume in Anisole, followed by PMMA 950 also diluted 4% by volume in Anisole. The spin coating was carried out at a spinning rate of 2500 rpm. The resists were subsequently baked at 110 °C for 5 min. Next, electron-beam lithography was performed using a Hitachi SU-70 scanning electron microscope (at an accelerating voltage of 30 kV and 60 pA beam current) with a Nabity NPGS lithography attachment. Finally, the resists were developed in methyl isobutyl ketone and isopropyl alcohol or MIBK-IPA (1:3) for 270 s followed by a cold IPA rinse.

For nanomagnet delineation, a 5-nm-thick Ti adhesion layer was first deposited on the patterned substrate using e-beam evaporation at a base pressure of ~2×10⁻⁷ Torr, followed by the deposition of Co. The lift-off was carried out using Remover PG solution.

A surface acoustic wave (SAW) was launched in the piezoelectric substrate with electrodes, and the SAW periodically strained the nanomagnets, causing their magnetizations to rotate owing to the inverse magnetostriction (Villari) effect. The rotating magnetizations emit EM waves (at the frequency of the SAW), which were detected in the far field by a dipole antenna coupled to a spectrum analyzer. The SAW (excitation) frequency was 144 MHz. The inventors were able to detect EM emissions at the same frequency that was 8 dBm above ambient emissions, at a distance >2 m from the antenna. A control sample (that contained no nanomagnets, but was otherwise identical to the actual sample) was used for background subtraction. The inventors were thus able to measure the EM emission from the nanomagnets at the exclusion of all other emitters (e.g. surface currents in the electrodes that are used to launch the SAW and any other spurious source radiating at or near 144 MHz).

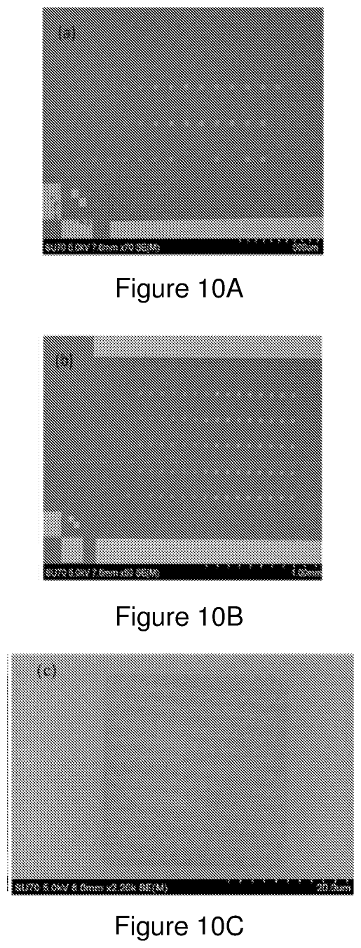

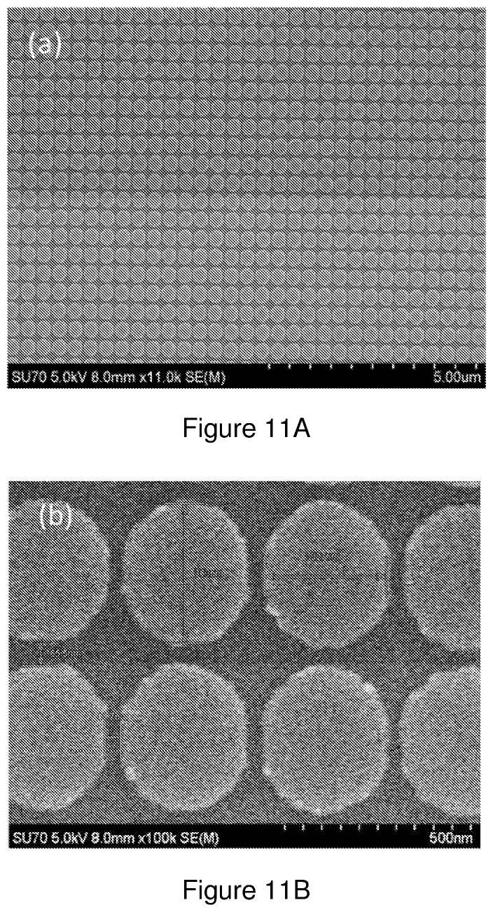

FIGS. 10A, 10B, and 10C show the scanning electron micrographs of the nanomagnet arrays that were fabricated. Two sets of samples were made: Sample A and Sample B. The former contained 55,000 nanomagnets and the latter 275,000 nanomagnets. FIGS. 10A and 10B show low magnification images of several rectangular arrays in the two samples (each white speck is an array). FIG. 10C shows a zoomed image of one such array (where the magnification is not enough to resolve individual nanomagnets). FIGS. 11A and 11B show the nanomagnets at higher magnifications that allow one to resolve individual nanomagnets.

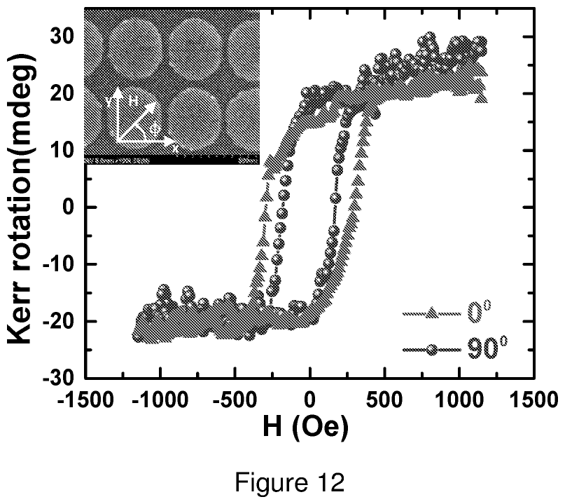

The magnetic behavior of the nanomagnets was characterized with static magneto-optical Kerr effect (S-MOKE) at room temperature. FIG. 12 shows the Kerr rotation versus magnetic field characteristics (hysteresis loops) under two situations: when the magnetic field is directed along the horizontal axis of the arrays and when directed along the vertical axis. The hysteresis loops confirm that the fabricated nanostructures are ferromagnetic at room temperature. The coercivity is 100 Oe higher when the magnetic field is directed along the horizontal axis which is parallel to the minor axes of the elliptical nanomagnets because this is the hard axis while the major axis is the easy axis.

In order to demonstrate the antenna function and also measure the antenna characteristics, SAW signal was launched in the substrate at two different frequencies (FSAW=144 MHz and 900 MHz). Any detectable EM emission (above the noise floor determined by ambient emissions) was measured at a distance >2 m from the samples. The detector was a dipole antenna calibrated to specific frequencies and these two frequencies belonged to that set, which is why they were chosen.

EM emissions were detected at 144 MHz, but not at 900 MHz which was too high a frequency for the magnetization of the nanomagnets to rotate. At 144 MHz, the EM wavelength is 2 m. Since the separation between the detector and the antenna was greater than the EM wavelength, we were measuring the far-field emission. The SAW velocity in the LiNbO₃ substrate is about 4100 m/sec, and hence the SAW wavelength is 28.4 μm at 144 MHz, while the EM wavelength is 2 m at that frequency. The ratio of the SAW to EM wavelength is thus 1.42×10⁻⁵.

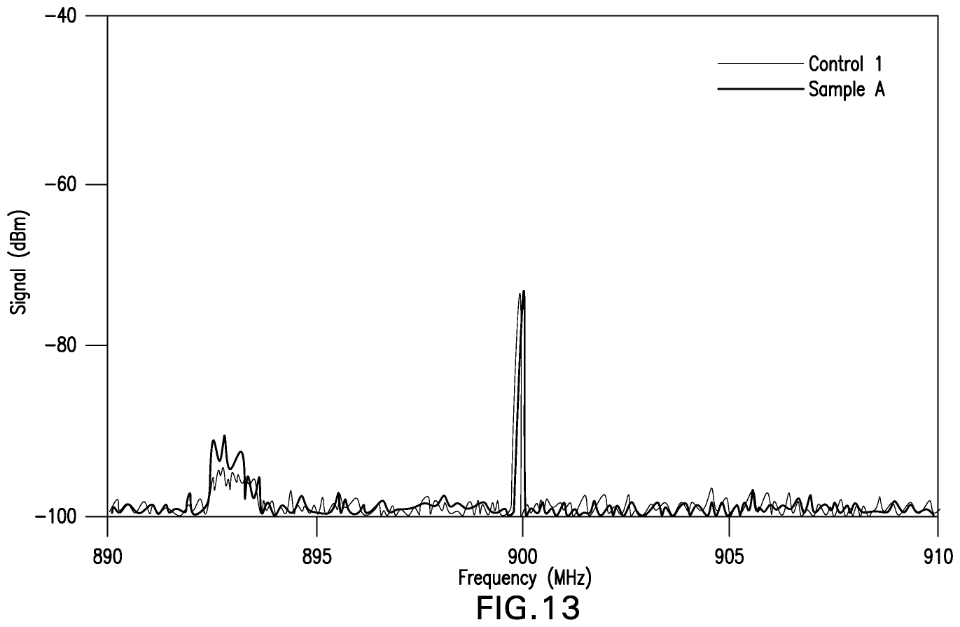

Measurements were made for both samples A and B containing nanomagnets, as well as control samples that were otherwise identical to the real samples but had no nanomagnets. FIG. 13 shows the detection results at F_{SAW}=900 MHz for Sample A (screenshots of the spectrum analyzer are shown in the Supplementary Material). There is ~1 dB difference between the 900 MHz emissions from the real sample (with nanomagnets) and the control sample (without nanomagnets), indicating that the nanomagnets are radiating very weakly at 900 MHz, if at all. Most likely, the nanomagnets do not radiate sufficiently because they are not able to rotate their magnetizations through sufficiently large angles at this high rate (900 MHz). Surface currents induced in the electrodes used to launch the SAW in both samples also radiate electromagnetic waves at 900 MHz and the detected emissions are primarily due to that. Similar (negative) result was obtained with Sample B.

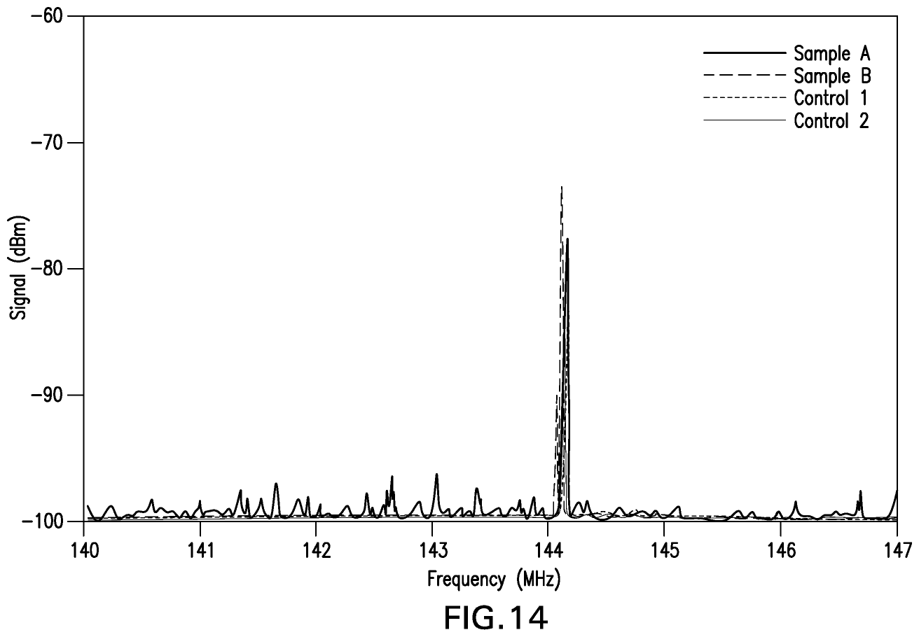

Past simulations by the inventors have shown that strain induced large angle magnetization rotation in single domain elliptical nanomagnets (of lateral dimension ~100 nm) typically takes place in about 1 ns. The nanomagnets used here were larger (>300 nm lateral dimension) and multidomain. Hence, it is possible that they rotate slower and therefore, the period of the 900 MHz signal (1.1 ns) does not allow them enough time to rotate through a large angle and radiate electromagnetic waves. Subsequently, the excitation frequency was reduced to 144 MHz. The detection results are shown in FIG. 14.

FIG. 14 clearly shows a measurable difference between the real samples and the control samples. The detected radiation power from Sample B is 8 dB higher than that from the control sample, while that from Sample A is 3 dB higher than that from the control sample. These differences indicate that the nanomagnets are able to rotate their magnetizations at this lower frequency and emit EM waves.

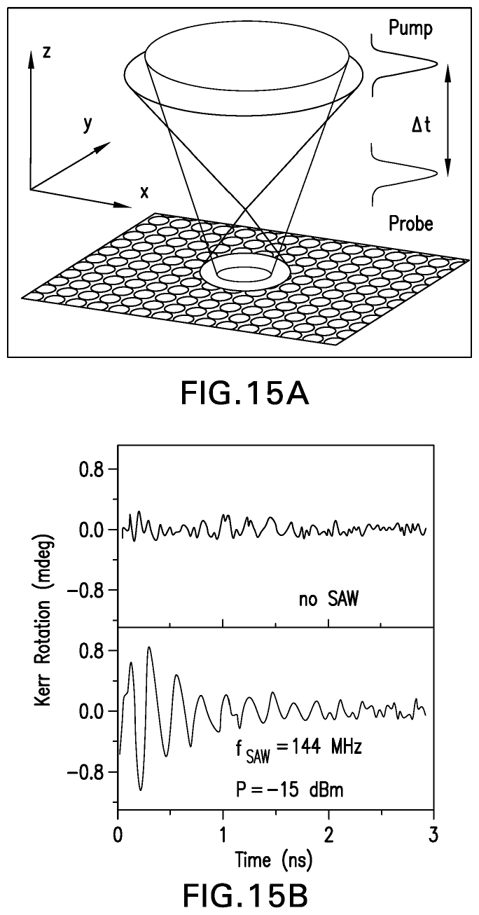

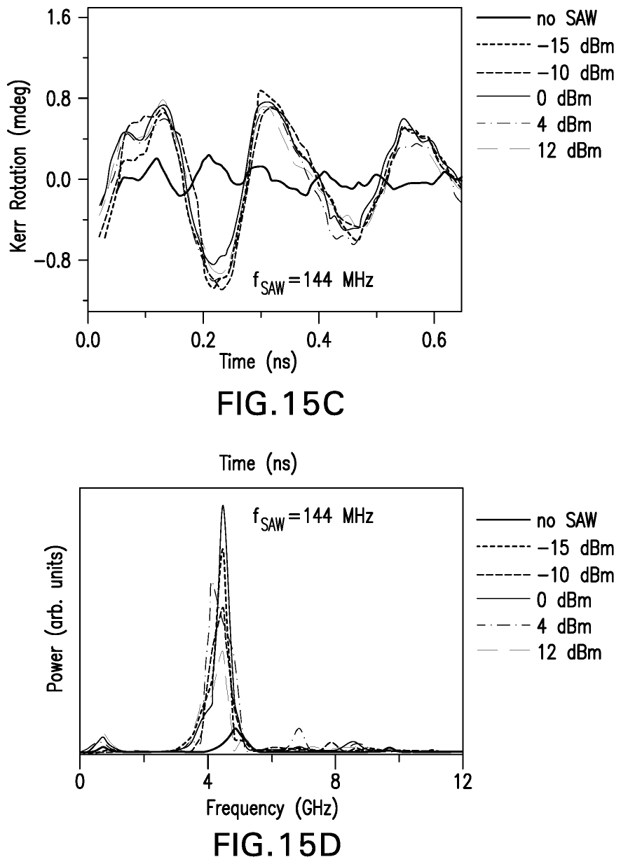

Time-resolved magneto-optical Kerr effect (TR-MOKE) measurements were also carried out on the nanomagnets at room temperature at various amplitudes of SAW excitation to verify that the launched SAW indeed has an effect on the magnetization rotation. The oscillations in time-resolved Kerr rotations were measured with a micro-focused optical pump-probe set up as shown in FIG. 15A. Details of the set-up (e.g. beam spot size, pulse width, repetition rate, etc.) can be found elsewhere and hence not repeated here. See, for example, S. Mondal, M. A. Abeed, K. Dutta, A. De, S. Sahoo, A. Barman and S. Bandyopadhyay, Hybrid magneto-dynamical modes in a single magnetostrictive nanomagnet on a piezoelectric substrate arising from magnetoelastic modulation of precessional dynamics, ACS Appl. Mater. Interfaces, 10, 43970-43977 (2018). See also A. Barman and J. Sinha in Spin Dynamics and Damping in Ferromagnetic Thin Films and Nanostructures, Springer International Publishing AG, (2018).

The measurements were done in the absence of any bias magnetic field. The ultrashort laser pulses used in the TR-MOKE measurements set up very high frequency (~4 GHZ) oscillations of the nanomagnets' magnetizations and surprisingly, it was found that the amplitudes of the Kerr oscillations resulting from these high frequency oscillations are significantly increased by the launched SAW with F_{SAW}=144 MHz. The amplitudes are markedly different in the absence of SAW versus in the presence of SAW. The amplitudes also show a rather weak dependence on the launched SAW power (P) for P>−15 dBm. These results are shown in FIGS. 15B and 15C.

It is noted that the SAW frequency (F_{SAW}=144 MHz) is more than an order of magnitude lower than the Kerr oscillation frequencies which are in the neighborhood of 4 GHz. The Kerr oscillations are not caused by the launched SAW. Instead, they are caused by the ultrashort laser pulses in the TR-MOKE set-up. The excitation by the femtosecond laser causes an ultrafast demagnetization of the nanomagnets followed by two-step relaxation (not shown) which also launches an ultrafast internal field to trigger magnetization precession of the nanomagnets. The absence of any bias magnetic field ensures that the magnetization precesses around an effective magnetic field due to the dipolar coupling fields between the nanomagnets, which leads to a dominant natural resonance frequency at around 4 GHz. Clearly the launched SAW strongly affects the amplitude of this resonant oscillation of magnetization despite being highly off-resonant and having a very weak SAW power. FIG. 15D shows the fast Fourier transforms (power spectral densities) of the Kerr oscillations for various SAW power. The ensuing power spectral densities are also affected by the SAW due to the variation in the magnetization oscillation amplitudes.

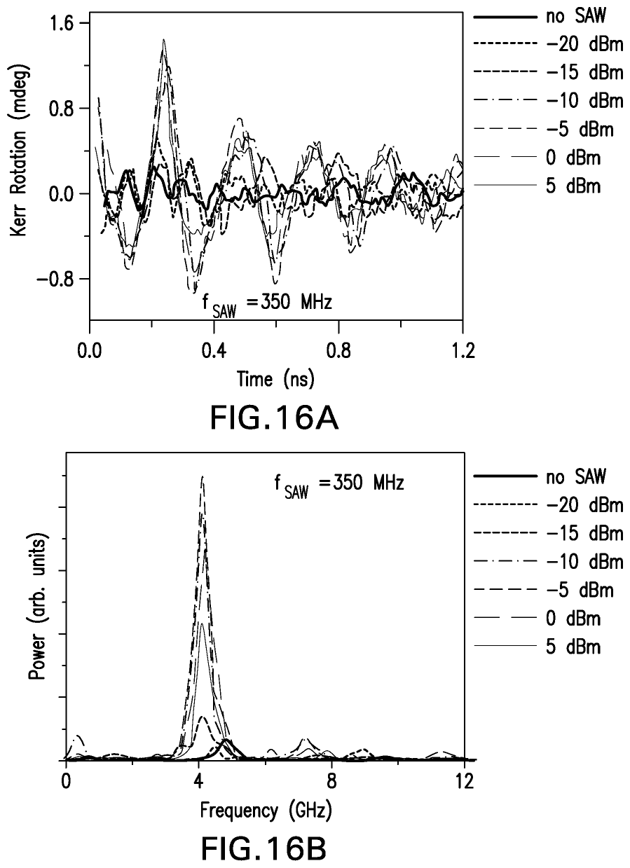

In the TR-MOKE experiments, it was not possible to detect any Kerr oscillation having a frequency component at the launched SAW frequency of 144 MHz because the time delay between the pump and probe laser (Δt) was only up to 3 ns and hence the lowest frequency component that could be resolved was about ⅓ ns, i.e. 333 MHz. Therefore, a SAW was launched of frequency F_{SAW}=350 MHz. The time-resolved Kerr rotations and their fast Fourier transforms are shown in FIGS. 16A and 16B. In FIG. 16B it is still not possible to detect any clear and consistent peak at 350 MHz. This indicates that either the SAW, by itself, cannot induce sufficient magnetization rotation at this high frequency of 350 MHz, or any signature of that rotation is being drowned by the much stronger Kerr oscillations caused not by the SAW, but by the ultrashort laser pulses. However, the clear observation that the SAW power affects Kerr oscillations significantly indicates unambiguously that the SAW affects magnetization oscillations and thus could be the source of the electromagnetic emission which is observed.

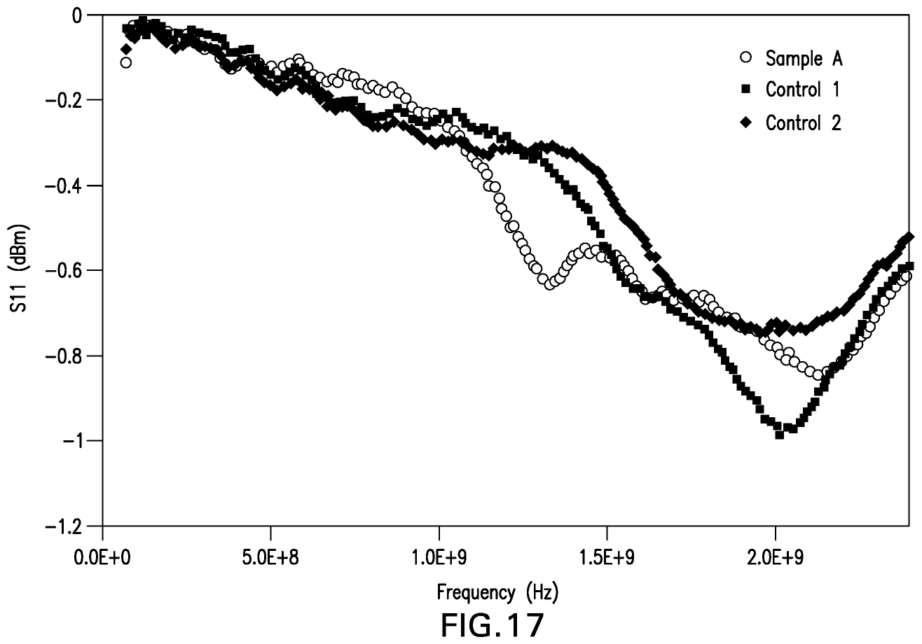

In FIG. 17, we show the reflection coefficient S11 (measured at the electrodes that launch the SAW) at the input power of 5 dbm (3.16 mW) as a function of frequency. The measurements are carried out with a network analyzer for Sample A, as well as the control samples. At the frequency of 144 MHz, ~85% of the input power is reflected back to the source because of impedance mismatch and hence only about 15% of the input power is coupled into the SAW. Therefore, the actual power fed to the antenna is 3.16×0.15=0.474 mW. This is the input power to Sample A, and the input power to Sample B is about the same.

The EM power from Sample B that is detected by the receiving dipole antenna is-73 dBm (see FIG. 14) which is about 50 pW. The power radiated by the control sample that is detected by the antenna is-81 dBm, which is 8 pW. Hence the power detected from the nanomagnets is 42 pW. The actual radiated power from Sample B is radiated over 4π solid angle and the fraction that is incident on the receiving dipole antenna is

$$\frac{lw}{4 π {r}^{2}}$$

where l is the length of the receiving antenna, w is its width and r is the separation between the source and the detector. In our case l=1 m, w=0.5 cm and r=2 m. Hence the ratio

$$\frac{lw}{4 π {r}^{2}}$$

is 10⁻⁴ and consequently, the power actually radiated by Sample B is 42×10⁴ pW=0.42 μW. Consequently, the radiation efficiency, which is the ratio of the radiated power to the input power, is 0.42 μW/0.474 mW=0.088% in the case of Sample B. In the case of Sample A, the detected power was-78 dBm, which is about 15 pW. Therefore, the power radiated by the nanomagnets in sample A was 15 pW−8 pW=7 pW. In this case, the efficiency is 0.07 μW/0.474 mW=0.014%. Since Sample A had 55,000 nanomagnets and Sample B had 275,000 nanomagnets, it is expected that the radiation from Sample A be weaker than the radiation from Sample B.

Now the

$$A / {λ}_{EM}^{2}$$

limit is calculated for both samples. The area of a nanomagnet is

$$\frac{π}{4} ( a \times b )$$

where a is the major axis dimension (360 nm) and b is the minor axis dimension (330 nm). Since there are 55,000 nanomagnets in Sample A, the radiating area is

$$A = \frac{π}{4} ( 360 \times 330 ) \times 1 {0}^{- 18} \times 55 , 000 = 5 \times 1 {0}^{- 9} {m}^{2} .$$

Hence, in the case of Sample A,

$$A / {λ}_{EM}^{2} = 1.25 \times 1 {0}^{- 9} ,$$

which means that the measured efficiency of 0.014% was able to beat the

$$A / {λ}_{EM}^{2}$$

limit by 112,000 times. In the case of Sample B, the radiating area is

$$A = \frac{π}{4} ( 360 \times 330 ) \times 1 {0}^{- 18} \times 275 , 000 = 2.5 \times 1 {0}^{- 8} {m}^{2} .$$

### Hence for Sample B,

$$A / {λ}_{EM}^{2} = 6.25 \times 1 {0}^{- 9} ,$$

which means that the measured efficiency of 0.088% was able to beat the

$$A / {λ}_{EM}^{2}$$

limit by 140,800 times in Sample B.

This Example demonstrates extreme sub-wavelength electromagnetic antennas whose radiation efficiencies greatly exceed the theoretical limit of

$$A / {λ}_{EM}^{2}$$

(A<λ_{EM}) [where A is the emitting area and λ_{EM} is the wavelength of the emitted electromagnetic wave] by a factor exceeding 10⁵. This allows new extents to the miniaturization of electromagnetic antennas. In this Example, the emitting areas of the antennas are about 2×10⁸ times smaller than the square of the emission wavelength. This drastic miniaturization was made possible by exciting the antennas at acoustic resonance instead of electromagnetic resonance. The surface acoustic waves were also found to amplify the magnetization response of these nanomagnets resonating in GHz frequencies, which is yet another application of the technology.

### Example 3. Resonantly Excited Magnonic-Crystal-Based Ultra-Sub-Wavelength Antenna for High Gain and Radiation Efficiency

An aspect of some embodiments is a resonant transfer of energy from SAW to spin waves mechanism to obtain very high radiation efficiencies at certain specific frequencies. As used in this disclosure, the phrase “very high,” in a context as it appears in the preceding sentence, means anything above 25%.

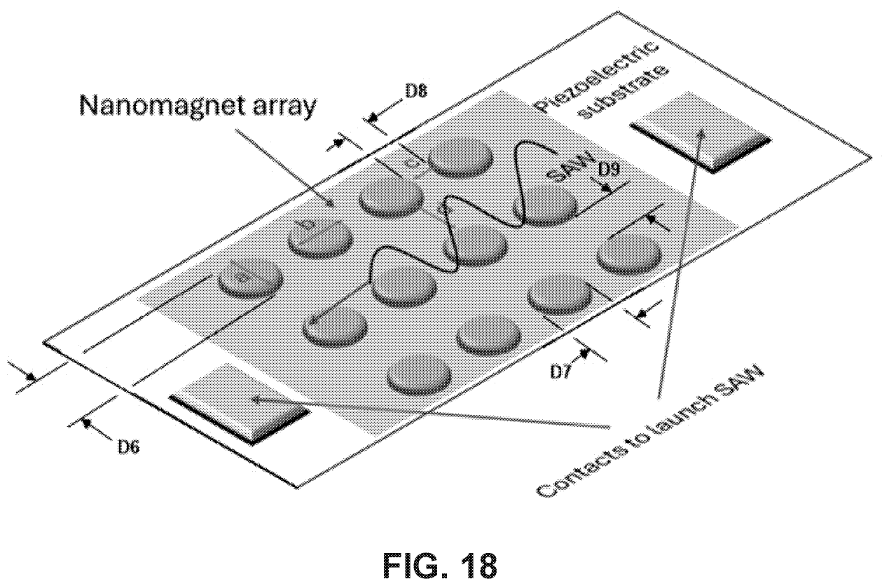

An artificial multiferroic magnonic crystal (AMMC) is a two-dimensional periodic array of (magnetostrictive) nanomagnets deposited on a piezoelectric substrate as shown in FIG. 18.

Referring to FIG. 18, the nanomagnets 1802 are arranged in a row-column manner on substrate 1804, each of the nanomagnets being somewhat elliptical, with a length D7 along a major axis shown aligned in the “row” and a width D6 along a minor axis aligned along a respective column axis. The D6 and D7 dimensions of the elliptical magnetostrictive nanomagnets 1802, in combination with the edge-to-edge spacing D8 in the row direction, i.e., the major axis of the nanomagnets, and the edge-to-edge spacing D9 in the “column” direction, in combination with the specific material for the nanomagnets 1802, establish the intrinsic mode frequencies.

When a SAW is launched in the substrate with electrodes delineated on the substrate, the nanomagnets are subjected to periodic strain, which produces spin waves in them owing to the Villari effect. The generation of spin waves is most efficient if the frequency of the SAW matches the frequency of an “intrinsic spin wave mode” of the AMMC. The frequencies corresponding to the intrinsic spin wave modes can be alternatively referred to as “intrinsic mode frequencies.” The intrinsic mode frequencies are determined by the AMMC parameters such as size, shape, geometry, spacing, material composition etc. and hence can be engineered by tailoring these parameters. Under such resonance conditions (SAW frequency=intrinsic mode frequency), energy from the SAW can be very efficiently transferred to the intrinsic spin wave mode to amplify the latter [1]. Stated more specifically, AMMC devices according to various embodiments can radiate electromagnetic waves by energy

transfer from spin waves to electromagnetic waves and can perform that energy transfer with very high efficiency if the spin waves are produced at intrinsic mode frequencies of the AMMC. This is made possible by making the SAW frequency match an intrinsic mode frequency. This in turn can implement ultra-sub-wavelength miniaturized antennas having very high radiation efficiency exceeding 25%. As will be appreciated by persons of ordinary from reading this disclosure in its entirety, the radiation efficiency shows as far exceeding the theoretical Harrington limit on the radiation efficiency of conventional antennas—at specific frequencies. The attainment of such efficiency is shown for example in the following Table 1, which shows measured radiation efficiency and gain, along with the corresponding Harrington limits, at specific frequencies, for two mutually orthogonal directions of SAW propagation, the two mutually orthogonal directions are labeled as “orientation 1” and “orientation 2”). Note that the efficiency is much higher at 5 GHz and 14 GHz than at other frequencies because these two are natural mode frequencies.

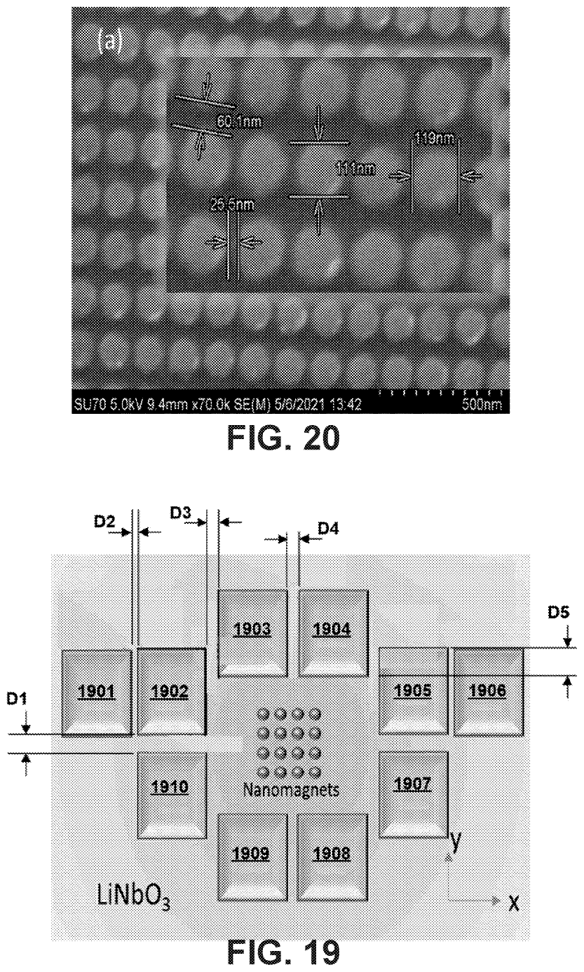

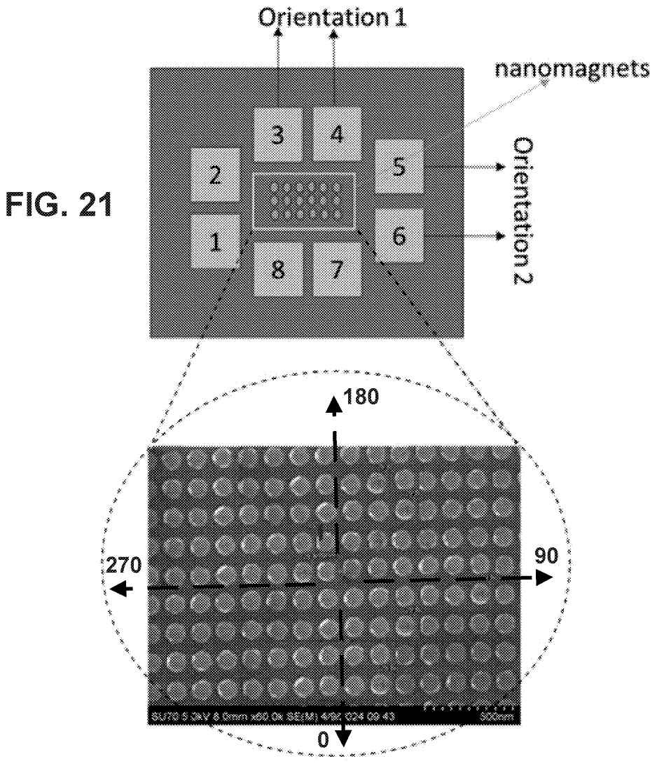

FIGS. 19 and 20 shows a spin-wave nano-antenna enabled by tripartite phonon-magnon-photon coupling. In overview, the phonons in the SAW excite spins waves in the nanomagnets via phonon-magnon coupling. The magnons then couple with radiative photon modes via magnon-photon coupling. This radiates EM waves with the same frequency as the magnons, which in turn have the same frequency as the photons. This implements an antenna if the SAW frequency is resonant with the intrinsic mode of magnonic crystal then amplified spin waves are produces which radiate very efficiently. If the SAW frequency is not resonant with the intrinsic frequency the radiating efficiency is much poorer.

Examples for the FIG. 19 illustrated implementation's dimensions D1, D2, D3, D4, and D5 are presented in the following Table 2.

TABLE 2
for FIG. 19

| Dimension | Example Value |
|---|---|
| D1 | 0.5 mm |
| D2 | 0.2 mm |
| D3 | 0.5 mm |
| D4 | 0.5 mm |
| D5 | 0.5 mm |

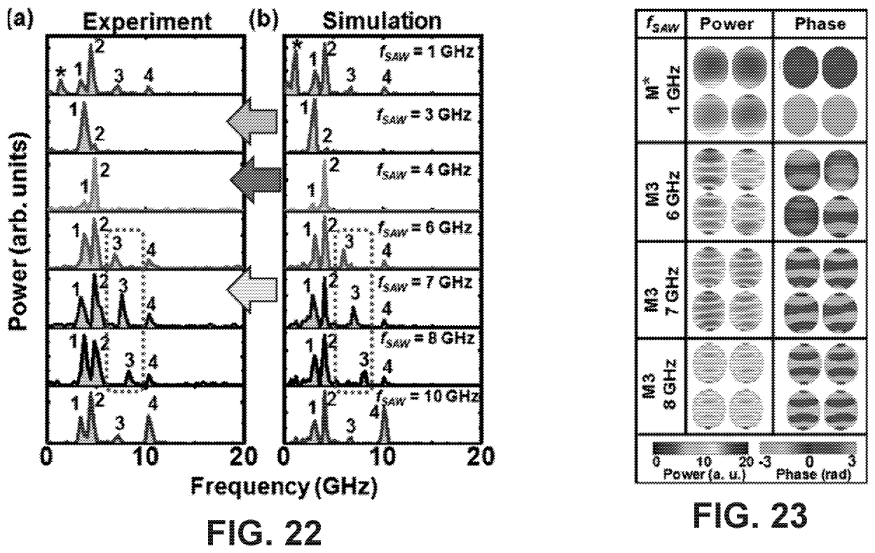

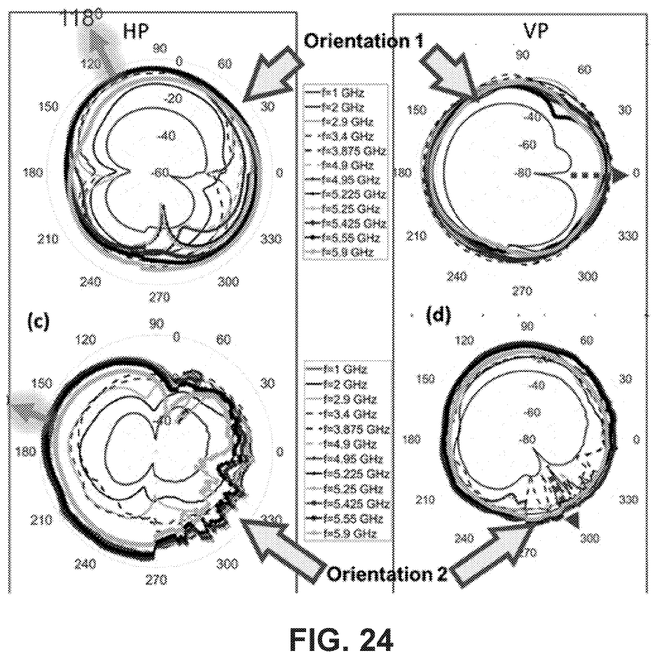

Referring to FIGS. 22 and 23, when the SAW frequency is not resonant with an intrinsic frequency, it generates an extrinsic mode at its own frequency, e.g., 1 GHz. When the SAW frequency is resonant with an intrinsic frequency, it amplifies the mode at that frequence while attenuating other intrinsic modes (see M3). Power is transferred from the SAW mode, showing phonon-magnon-coupling. Examples are 3.1 GHz and 4.2 GHz. These are intrinsic modes at the frequencies and when SAWs of these frequencies are launched the intrinsic powers at these frequencies are amplified by 7.2.

Features and advantages of ultra-sub-wavelength antenna according to various embodiments further include, for example and without limitation, radiation efficiency and gain that can exceed the theoretical limit on the gain and radiation efficiency of a conventional antenna of the same size by several orders of magnitude. These features and advantages can in turn enable various applications such as, for example and without limitation, medically implantable health-monitoring devices, stealth devices for military and law-enforcement application, various further and additional avenues of energy harvesting, and improved performance personal communicators, etc.

Other applications can include, for example and without limitation, simultaneous radiation of multiple frequencies by launching a polychromatic SAW having frequency components that match the intrinsic mode frequencies of the AMMC.

Exemplary embodiments include, for example, aggressive antenna miniaturization to enable all manner of embedded applications where the antenna size has to be small enough to fit inside a small space (e.g., human body or stealth drones) that is much smaller than the electromagnetic wavelength at the operating frequency. For example, high frequency radiation is harmful to human tissue. Hence medically implanted antennas must operate at relatively low frequencies such as 100 MHz or lower. The electromagnetic wavelength at 100 MHz is 3 meters. Since no implantable antenna can be that large, the antenna must be much smaller than the wavelength. All conventional antennas much smaller than the wavelength have poor efficiencies owing to the Harrington limit which stipulates that the radiation efficiency is limited to A/λ2, where A is the antenna area and λ is the wavelength. Clearly, the efficiency will plummet if A<<|λ2. This is an obstacle to miniaturization of antennas. An exemplary mechanism according to this disclosure is unconventional and therefore can overcome the Harrington limit. The inventor has demonstrated overcoming the Harrington limit by more than 5 orders of magnitude at some specific frequencies that correspond to the natural mode frequencies of the AMMC used in the experiment. Exemplary embodiments include, for example, antennas for embedded applications. Exemplary embodiments include, for example, an ultra-sub-wavelength antenna, implemented with an artificial multiferroic magnonic crystal and activated with a surface acoustic wave (SAW), that exhibits extremely high radiation efficiency at specific frequencies due to resonant transfer of energy from the SAW to intrinsic spin wave. The radiation efficiency and gain exceed the Harrington limits that constrain conventional antennas by several orders of magnitude.

In this disclosure, where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are described.

While exemplary embodiments of the present invention have been disclosed herein, one skilled in the art will recognize that various changes and modifications may be made without departing from the scope of the invention as defined by the following claims.

We claim:

1. A subwavelength electromagnetic antenna, comprising a piezoelectric substrate;
an array of magnetostrictive nanomagnets in elastic contact with the piezoelectric substrate, and
a plurality of conductive terminals, supported on the piezoelectric substrate and configured to receive from a driver an input electrical current signal comprising any among i) a first frequency electrical signal, ii) a second frequency electrical signal, and iii) a combination of i) and ii),
wherein:
the array of magnetostrictive nanomagnets is further configured with a geometry and a spatial arrangement such that the array resonates at a plurality of different implicit mode frequencies, including at least a first implicit mode frequency and a second implicit mode frequency,
the geometry includes the magnetostrictive nanomagnets having respective three-dimensional (3D) surface geometries and having respective lengths parallel to a first axis and widths parallel to a second axis perpendicular to the first axis, and
the spatial arrangement comprises the magnetostrictive nanomagnets being spaced apart with first axis edge-to-edge separations parallel to the first axis, and second axis edge-to-edge separations parallel to the second axis,
the plurality of conductive terminals are further configured to launch, in the piezoelectric substrate toward the array of magnetostrictive nanomagnets, in the direction of the first axis,
iv) a first frequency surface acoustic wave (SAW) in response to receiving the first frequency electrical signal,
v) a second frequency SAW in response to receiving the second frequency electrical signal, and
vi) the first frequency SAW and the second frequency SAW launch, concurrently, in response to receiving, concurrently, the first frequency electrical signal and the second frequency electrical signal,
the array of magnetostrictive nanomagnets, based at least in part on being further configured to resonate at the plurality of different implicit mode frequencies, produces, when the SAW energy is at the first implicit mode frequency and/or the second implicit mode frequency, a resonant transferring of the SAW energy to the spin wave in the array of magnetostrictive nanomagnets, which causes large amplitude spin precession, such that the resonantly excited spin waves at the first implicit mode frequency and or the second implicit frequency radiate electromagnetic waves with high radiation efficiencies, and
wherein the driver and the plurality of conductive terminals are configured such that SAWs are launched into the piezoelectric substrate at one or both of the first and the second implicit mode frequencies, providing high radiation efficiencies.

2. A method for transmitting electromagnetic signals from a subwavelength electromagnetic antenna, comprising:
feeding, from a driver circuit, to conductive terminals on a piezoelectric substrate an input electrical signal comprising any among i) a first frequency electrical signal, ii) a second frequency electrical signal, and iii) a combination of i) and ii), the piezoelectric substrate also supporting an array of magnetostrictive nanomagnets configured with a geometry and a spatial arrangement such that the array resonates at a plurality of different implicit mode frequencies, including at least a first implicit mode frequency and a second implicit mode frequency,
the geometry including the magnetostrictive nanomagnets having respective three-dimensional (3D) surface geometries, and having respective lengths parallel to a first axis and widths parallel to a second axis perpendicular to the first axis, and
the spatial arrangement comprising the magnetostrictive nanomagnets being spaced apart by first axis edge-to-edge separations parallel to the first axis, and second axis edge-to-edge separations parallel to the second axis,
the conductive terminals launching, in the piezoelectric substrate toward the array of magnetostrictive nanomagnets, in the direction of the first axis, in response to receiving the input electrical signal: iv) a first frequency surface acoustic wave (SAW) when the input electrical signal includes the first frequency electrical signal, v) a second frequency SAW when the input electrical signal includes the second frequency electrical signal, and vi) the first frequency SAW and the second frequency SAW, concurrently, when the input electrical signal has both the first frequency electrical signal and the second frequency electrical signal,
the piezoelectric substrate resonantly transferring the SAW energy to a spin wave in the array of magnetostrictive nanomagnets in the array of magnetostrictive nanomagnets, in response to the SAW energy being at the first implicit mode frequency and/or at the second implicit mode frequency, producing cause large amplitude spin precession, such that the resonantly excited spin waves at the first implicit mode frequency and/or the second implicit frequency radiate electromagnetic waves with high radiation efficiencies.
